(19) United States
(12) Patent Application Publication
(10) Pub. No.: US 2026/0082780 A1
(43) Pub. Date: Mar. 19, 2026

(54) DISPLAY PANEL AND ELECTRONIC APPARATUS INCLUDING THE SAME

(71) Applicant: Samsung Display Co., Ltd., Yongin-si (KR)

(72) Inventors: HEEJU WOO, Yongin-si (KR); KIYONG KIM, Yongin-si (KR); CHOLONG WON, Yongin-si (KR); HYUNGBIN CHO, Yongin-si (KR)

(21) Appl. No.: 19/240,579

(22) Filed: Jun. 17, 2025

(30) Foreign Application Priority Data
Sep. 19, 2024 (KR) 10-2024-0126858

(51) Int. Cl. H10K 59/131; H10K 59/124

(52) U.S. Cl. CPC H10K 59/131; H10K 59/124

(57) ABSTRACT

A display panel includes a display region including a pixel and a non-display region including a pad region. A signal pad is connected to the pixel through a signal line is disposed in the pad region. The signal pad includes a first conductive pattern connected to a portion of the signal line, a second conductive pattern disposed on the first conductive pattern, a third conductive pattern disposed on the second conductive pattern, and an insulating pattern disposed between the second conductive pattern and the third conductive pattern. The insulating pattern includes a first insulating pattern and a second insulating pattern disposed at the same layer as the first insulating pattern. The first insulating pattern and the second insulating pattern are in contact with each other, and the hardness of the first insulating pattern is greater than the hardness of the second insulating pattern.

This application claims priority to Korean Patent Application No. 10-2024-0126858, filed on Sep. 19, 2024, and all the benefits accruing therefrom under 35 USC § 119, the content of which in its entirety is herein incorporated by reference.

### BACKGROUND

The disclosure herein relates to a display panel and an electronic apparatus including the same, and more particularly, to a display panel including a pad region and an electronic apparatus.

Multimedia electronic apparatuses such as televisions, mobile phones, tablets, navigation systems, and game consoles may include a display module which displays images and senses external inputs.

The display module may be electrically connected to a data driver, which provides electrical signals necessary for displaying images, by being bonded thereto.

### SUMMARY

The disclosure provides a display panel and an electronic apparatus which have excellent bonding reliability.

An embodiment of the inventive concept provides a display panel in which a display region including a pixel and a non-display region disposed adjacent to the display region and including a pad region are defined, wherein a signal pad connected to the pixel through a signal line is disposed in the pad region, and wherein the signal pad includes: a first conductive pattern connected to a portion of the signal line; a second conductive pattern disposed on the first conductive pattern; a third conductive pattern disposed on the second conductive pattern; and an insulating pattern disposed between the second conductive pattern and the third conductive pattern, wherein the insulating pattern includes a first insulating pattern and a second insulating pattern disposed at the same layer as the first insulating pattern, wherein the first insulating pattern and the second insulating pattern are in contact with each other, and a hardness of the first insulating pattern is greater than a hardness of the second insulating pattern.

In an embodiment, each of the first insulating pattern and the second insulating pattern may include a lower surface adjacent to the second conductive pattern, an upper surface opposite the lower surface, and a side surface connecting the lower surface and the upper surface to each other, wherein a portion of the side surface of the first insulating pattern and a portion of the side surface of the second insulating pattern may be in contact with each other.

In an embodiment, the upper surface of the first insulating pattern may include a flat surface, and the upper surface of the second insulating pattern may include a curved surface.

In an embodiment, the first insulating pattern may be formed from a negative photoresist material, and the second insulating pattern may be formed from a positive photoresist material.

In an embodiment, the upper surface of the first insulating pattern may include a flat surface, and the upper surface of the second insulating pattern may include a flat surface.

In an embodiment, the first insulating pattern may be formed from a negative photoresist material, and the second insulating pattern may be formed from a negative photoresist material.

In an embodiment, the hardness of the first insulating pattern may be about 5 (gigapascals) GPa to about 15 GPa, and the hardness of the second insulating pattern may be about 1 GPa to about 5 GPa.

In an embodiment, the thickness of the first insulating pattern may be the same as the thickness of the second insulating pattern.

In an embodiment, the thickness of the first insulating pattern may be greater than the thickness of the second insulating pattern, and the first insulating pattern may protrude in a direction toward the third conductive pattern compared to the second insulating pattern.

In an embodiment, the insulating pattern may be provided in plurality, and the plurality of insulating patterns may be spaced apart from each other in a plan view.

In an embodiment of the inventive concept, a display panel is provided in which a display region including a pixel and a non-display region adjacent to the display region and including a pad region are defined, wherein a signal pad connected to the pixel through a signal line is disposed in the pad region, and wherein the signal pad includes: a first conductive pattern connected to a portion of the signal line; a second conductive pattern disposed on the first conductive pattern; a third conductive pattern disposed on the second conductive pattern; and an insulating pattern disposed between the second conductive pattern and the third conductive pattern, wherein the insulating pattern includes a first insulating pattern and a second insulating pattern disposed at the same layer as the first insulating pattern, wherein the first insulating pattern and the second insulating pattern are in contact with each other, the thickness of the first insulating pattern is greater than the thickness of the second insulating pattern, and the first insulating pattern protrudes in a direction toward the third conductive pattern compared to the second insulating pattern.

In an embodiment, each of the first insulating pattern and the second insulating pattern includes a lower surface adjacent to the second conductive pattern, an upper surface opposite the lower surface, and a side surface connecting the lower surface and the upper surface to each other, wherein a portion of the side surface of the first insulating pattern and a portion of the side surface of the second insulating pattern may be in contact with each other.

In an embodiment, the upper surface of the first insulating pattern may include a flat surface, and the upper surface of the second insulating pattern may include a curved surface.

In an embodiment, the first insulating pattern may be formed from a negative photoresist material, and the second insulating pattern may be formed from a positive photoresist material.

In an embodiment, the upper surface of the first insulating pattern may include a flat surface, and the upper surface of the second insulating pattern may include a flat surface.

In an embodiment, the first insulating pattern may be formed from a negative photoresist material, and the second insulating pattern may be formed from a negative photoresist material.

In an embodiment, a hardness of the first insulating pattern may be greater than a hardness of the second insulating pattern.

In an embodiment, the hardness of the first insulating pattern may be about 5 GPa to about 15 GPa, and the hardness of the second insulating pattern may be about 1 GPa and about 5 GPa.

In an embodiment, the insulating pattern may be provided in plurality, and the plurality of insulating patterns may be spaced apart from each other in a plan view.

In an embodiment of the inventive concept, an electronic apparatus includes: a display module including a display panel, which includes a display region including a pixel and a non-display region including a pad region and adjacent to the display region, and an input sensing unit disposed on the display panel; an electronic component including a bump electrode and disposed on the pad region; and an adhesive layer which bonds the display panel and the electronic component to each other, wherein a signal pad connected to the pixel through a signal line is disposed in the pad region, and wherein the signal pad includes: a first conductive pattern connected to a portion of the signal line; a second conductive pattern disposed on the first conductive pattern; a third conductive pattern disposed on the second conductive pattern; and an insulating pattern disposed between the second conductive pattern and the third conductive pattern, wherein the insulating pattern includes a first insulating pattern and a second insulating pattern disposed at the same layer as the first insulating pattern, wherein the first insulating pattern and the second insulating pattern are in contact with each other, the thickness of the first insulating pattern is greater than the thickness of the second insulating pattern, the first insulating pattern protrudes in a direction toward the third conductive pattern compared to the second insulating pattern, and the hardness of the first insulating pattern is greater than the hardness of the second insulating pattern.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a perspective view of an electronic apparatus according to an embodiment of the inventive concept;

FIG. 2 is a separated perspective view of the electronic apparatus according to an embodiment of the inventive concept;

FIG. 3 is a cross-sectional view of a display module according to an embodiment of the inventive concept;

FIG. 4 is a plan view of a display panel according to an embodiment of the inventive concept;

FIG. 5 is a plan view of an input sensing unit according to an embodiment of the inventive concept;

FIG. 6 is a cross-sectional view of the display module according to an embodiment of the inventive concept;

FIG. 7 is a perspective view of the electronic apparatus according to an embodiment of the inventive concept;

FIG. 8A is a plan view of a pad region according to an embodiment of the inventive concept;

FIG. 8B is a cross-sectional view of the pad region according to an embodiment of the inventive concept;

FIG. 8C is a cross-sectional view illustrating a bonding structure of a display device according to an embodiment of the inventive concept; and

FIG. 9A and FIG. 9B each depict a cross-sectional view of the pad region according to an embodiment of the inventive concept.

### DETAILED DESCRIPTION

In the disclosure, various modifications can be made, various forms can be used, and specific embodiments will be illustrated in the drawings and described in detail in the text. However, this is not intended to limit the disclosure to a specific form disclosed, and it will be understood which all changes, equivalents, or substitutes which fall in the spirit and technical scope of the disclosure should be included.

In this specification, singular expressions include plural expressions unless the context clearly indicates otherwise.

In this specification, it will be understood which the terms “include” and/or “have”, when used in this specification, specify the presence of stated features, integers, steps, operations, elements, components and/or groups thereof, but do not preclude the presence or addition of one or more other features, integers, steps, operations, elements, components, and/or groups thereof.

In this specification, it will be understood which when an element (or region, layer, portion, etc.) is referred to as being “on”, “connected to” or “coupled to” another element, it can be directly on, connected or coupled to the other element, or intervening elements may be present.

In addition, terms, such as “below”, “lower”, “above”, “upper” and the like, are used herein for ease of description to describe one element's relation to another element(s) as illustrated in the figures. The above terms are relative concepts and are described based on the directions indicated in the drawings.

In this specification, the expression “being disposed on” may refer to being disposed on the upper portion as well as the lower portion of any given member.

In this specification, the expression “being directly disposed” may mean which there is no layer, film, region, plate, or the like, which is added between a portion of a layer, film, region, plate, or the like and another portion. For example, the expression “being directly disposed” may mean being disposed between two layers or two members without an additional member such as an adhesive member interposed therebetween.

In this specification, the term “and/or” includes any and all combinations which the associated configurations can define.

It will be understood which, although the terms first, second, etc. may be used herein to describe various elements, these elements should not be limited by these terms. These terms are only used to distinguish one element from another element. For example, a first element could be termed a second element without departing from the scope of the disclosure. Similarly, the second element may also be referred to as the first element.

Unless otherwise defined, all terms (including technical and scientific terms) used herein have the same meaning as commonly understood by one of ordinary skill in the art to which this disclosure belongs. It will be further understood which terms, such as those defined in commonly used dictionaries, should be interpreted as having a meaning which is consistent with their meaning in the context of the relevant art and will not be interpreted in an idealized or overly formal sense unless expressly so defined herein.

Like reference numerals refer to like elements throughout. In addition, in the drawings, the thicknesses, ratios, and dimensions of elements are exaggerated for effective description of the technical contents.

Hereinafter, embodiments of the inventive concept will be described with reference to the accompanying drawings.

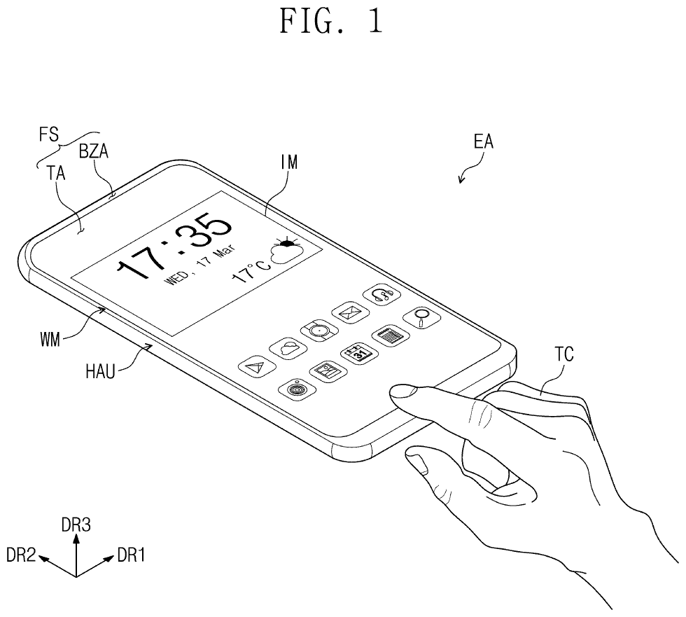

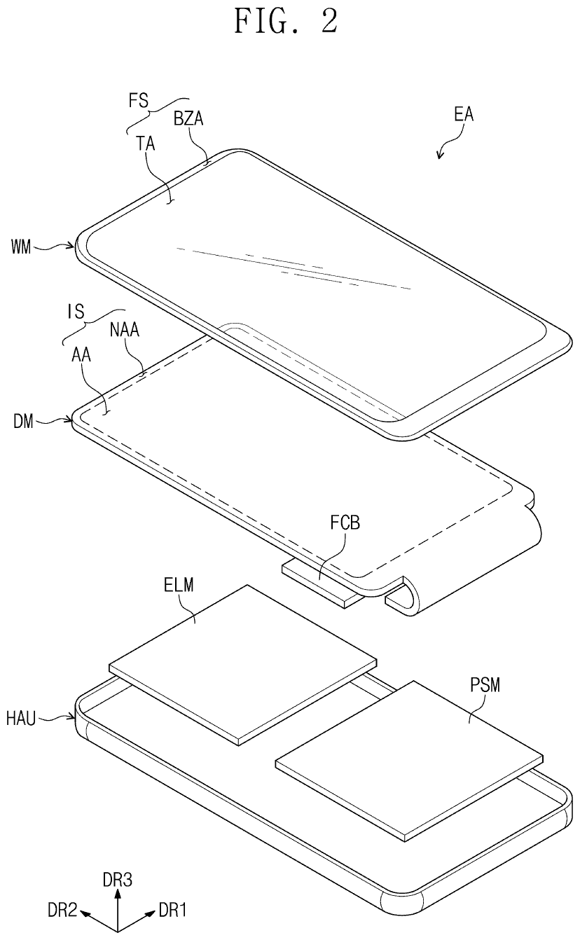

FIG. 1 is a perspective view of an electronic apparatus EA according to an embodiment of the inventive concept. FIG. 2 is a separated perspective view of the electronic apparatus EA according to an embodiment of the inventive concept.

Referring to FIGS. 1 and 2, the electronic apparatus EA may be activated according to an electrical signal, display an image IM, and sense an external input TC. For example, the electronic apparatus EA may be implemented as various devices including, but not limited to, a monitor, a mobile phone, a tablet, a navigation system, and a game console. However, the embodiments of the electronic apparatus EA described above are exemplary and are not limited thereto as long as they do not depart from the concept of the disclosure. In this embodiment, the electronic apparatus EA is exemplarily illustrated as a mobile phone.

In a plan view, the electronic apparatus EA may have a rectangular shape having short sides extending in a first direction DR1 and long sides extending in a second direction DR2 crossing the first direction DR1. Without being limited thereto, however, in a plan view the electronic apparatus EA may have various shapes such as a circle or a polygon.

In this embodiment, a third direction DR3 may be defined as a direction perpendicular to a plane or in a “plan view” defined by the first direction DR1 and the second direction DR2. The front surface (or upper surface) and the rear surface (or lower surface) of each member constituting the electronic apparatus EA may face each other in the third direction DR3, and the normal direction of each of the front and rear surfaces may be substantially parallel to the third direction DR3. A separation distance between the front and rear surfaces of a member defined along the third direction DR3 may correspond to the thickness of the member.

In this specification, the expression “on a plane” or “in a plan view” may be defined as a state viewed from the third direction DR3. In this specification, the expression “on a cross section” may be defined as a state viewed from the first direction DR1 or the second direction DR2. The directions indicated by the first to third directions DR1, DR2, and DR3 are relative concepts and may be converted into other directions.

The electronic apparatus EA may be rigid or flexible. The expression “being flexible” means a property of being bendable, and a flexible structure may include everything from a completely foldable structure to a structure which can be bent to the level of several nanometers. For example, a flexible electronic apparatus EA may include a curved, rollable, and/or foldable electronic apparatus.

The electronic apparatus EA may display an image IM through a display surface FS parallel to each of the first direction DR1 and the second direction DR2. The image IM may include a still image as well as a dynamic image. FIG. 1 illustrates a clock and icons as an example of the image IM.

The display surface FS of the electronic apparatus EA may include only a flat surface, or may further include a curved surface bent from at least one side of the flat surface. The display surface FS may correspond to the front surface of the electronic apparatus EA and may also correspond to the front surface of a window WM. Hereinafter, the display surface FS of the electronic apparatus EA and the front surface FS of the window WM will use the same reference numeral.

The electronic apparatus EA according to an embodiment of the inventive concept may sense an external input TC applied from the outside. The external input TC may include various types of inputs including, but not limited to, as force, pressure, temperature, or light. In this embodiment, the external input TC is illustrated as a user's hand applied to the front surface of the electronic apparatus EA. However, this is illustrated as an example, and the external input TC may include a touch by a pen or an input, such as hovering, applied in proximity to the electronic apparatus EA.

The electronic apparatus EA may sense a user's input through the display surface FS defined on the front surface and respond to the sensed input signal. However, the region of the electronic apparatus EA which senses the external input TC is not limited to the front surface of the electronic apparatus EA and may change depending on the design of the electronic apparatus EA. For example, the electronic apparatus EA may also sense a user's input applied to the side surface or rear surface of the electronic apparatus EA.

The electronic apparatus EA may include a window WM, a display module DM, an electronic module ELM, a power module PSM, and a housing HAU. The window WM and the housing HAU may be coupled to each other to form the exterior of the electronic apparatus EA.

The window WM may be disposed on the display module DM. The window WM may cover the front surface IS of the display module DM and protect the display module DM from an external impact and scratch. The window WM may be coupled to the display module DM by an adhesive layer.

The window WM may include an optically transparent insulating material. For example, the window WM may include glass or a synthetic resin as a base film. The window WM may have a single-layer or multi-layer structure. For example, the window WM having a multi-layer structure may include synthetic resin films bonded to each other by an adhesive, or may include a glass film and a synthetic resin film bonded to each other by an adhesive. The window WM may further include a functional layer, such as an anti-fingerprint layer, a phase control layer, and a hard coating layer, disposed on a transparent base film.

The front surface FS of the window WM may correspond to the front surface FS of the electronic apparatus EA. The front surface FS of the window WM may include a transmission region TA and a bezel region BZA.

The transmission region TA may be an optically transparent region. The transmission region TA may transmit an image IM provided by the display module DM. In this embodiment, the transmission region TA is illustrated as a square shape, but without being limited thereto, the transmission region TA may have various shapes.

The bezel region BZA may have a lower light transmittance than the transmission region TA. The bezel region BZA may correspond to a region in which a material having a color is printed. As the bezel region BZA prevents light transmission, it is possible to prevent a configuration of the display module DM, which is disposed to overlap the bezel region BZA, from being visually recognized from the outside.

The bezel region BZA may be adjacent to the transmission region TA. The shape of the transmission region TA may be substantially defined by the bezel region BZA. For example, the bezel region BZA may be disposed outside and surround the transmission region TA. However, this is illustrated as an example, and the bezel region BZA may be adjacent to only one side of the transmission region TA or may be disposed on a side surface of the electronic apparatus EA, not on the front surface thereof. In addition, the bezel region BZA may be omitted.

The display module DM may be disposed between the window WM and the housing HAU. The display module DM may display an image IM and sense an external input TC. The image IM may be displayed on the front surface IS of the display module DM. The front surface IS of the display module DM may include an active region AA and a peripheral region NAA.

The active region AA may be activated according to an electrical signal. For example, the active region AA may be a region in which an image IM is displayed and an external input TC is also sensed. The active region AA may overlap at least a portion of the transmission region TA. Accordingly, a user may visually recognize the image IM or provide the external input TC through the transmission region TA. However, this is an example, and within the active region AA, a region in which the image IM is displayed and a region in which the external input TC is sensed may be separated from each other, and the inventive concept is not limited to any one embodiment.

The peripheral region NAA may be adjacent to the active region AA. For example, the peripheral region NAA may surround the active region AA. A driving circuit, a driving line, or the like for driving the active region AA may be disposed in the peripheral region NAA. The peripheral region NAA may overlap at least a portion of the bezel region BZA, and the components disposed in the peripheral region NAA may be prevented from being viewed from the outside by the bezel region BZA.

The display module DM may include a display panel and an input sensing unit. The display panel may display an image IM, and the input sensing unit may sense an external input TC. A detailed description thereof will be provided later.

A portion of the display module DM may be bent with respect to a bending axis extending in the first direction DR1. That is, the portion of the display module DM may be bent toward the rear surface of the display module DM corresponding to the active region AA. A flexible circuit board FCB may be connected to a portion of the bent display module DM. Accordingly, in a plan view the flexible circuit board FCB may overlap the display module DM.

The flexible circuit board FCB may be electrically connected to the display module DM on one side of the display module DM. The flexible circuit board FCB may generate an electrical signal to be provided to the display module DM or receive a signal generated by the display module DM to calculate a result value including the information on the position or intensity of the sensed external input TC.

The electronic module ELM and the power module PSM may be disposed below the display module DM. The electronic module ELM and the power module PSM may be electrically connected to each other through a separate circuit board.

The power module PSM may supply power required for the operation of the electronic apparatus EA. For example, the power module PSM may include a conventional battery module.

The electronic module ELM may include various functional modules which operate the electronic apparatus EA. For example, the electronic module ELM may include, but is not limited to, a control module, a wireless communication module, an image input module, an audio input module, an audio output module, a memory, an optical module, and an external interface module. The electronic module ELM may include, but is not limited to, a main circuit board, and the modules of the electronic module ELM may be mounted on the main circuit board or electrically connected to the main circuit board through a separate circuit board.

The control module among the electronic modules ELM may control the overall operation of the electronic apparatus EA. For example, the control module may activate and deactivate the display module DM in accordance with a user input. The control module may include at least one microprocessor. The optical module among the electronic modules ELM may include, but is not limited to, a camera module, a proximity sensor, a biometric sensor for recognizing a user's body part (e.g., a fingerprint, iris, or face), a lamp for outputting light, or the like.

The housing HAU may be coupled to the window WM and provide an internal space for accommodating the display module DM, the electronic module ELM, the power module PSM, and the flexible circuit board FCB. The housing HAU may include a material having relatively high rigidity. For example, the housing HAU may include a plurality of frames and/or plates made of glass, plastic, or metal, or a combination thereof. The housing HAU may protect the components of the electronic apparatus EA accommodated in the housing HAU by absorbing an impact applied from the outside or preventing foreign substances/moisture, etc. from entering from the outside.

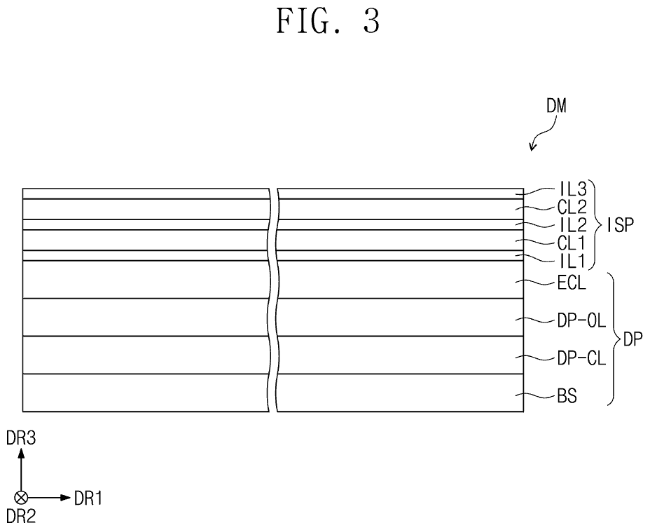

FIG. 3 is a cross-sectional view of a display module DM according to an embodiment of the inventive concept.

Referring to FIG. 3, the display module DM may include a display panel DP and an input sensing unit ISP. The input sensing unit ISP may be disposed on the display panel DP. For example, the input sensing unit ISP may be disposed directly on the display panel DP. In this embodiment, the expression “the input sensing unit ISP is disposed directly on the display panel DP” means which the input sensing unit ISP is formed on the display panel DP through a continuous process so which the input sensing unit ISP and the display panel DP are coupled to each other without a separate adhesive layer. In other words, the components of the input sensing unit ISP may be formed on a base surface provided by the display panel DP.

The display panel DP may display an image according to an electrical signal. The display panel DP according to an embodiment of the inventive concept may be a light-emitting display panel, but is not particularly limited thereto. For example, the display panel DP may be an organic light-emitting display panel, an inorganic light-emitting display panel, or a quantum dot light-emitting display panel. A light-emitting layer of the organic light-emitting display panel may include an organic light-emitting material, and a light-emitting layer of the inorganic light-emitting display panel may include an inorganic light-emitting material. A light-emitting layer of the quantum dot light-emitting display panel may include quantum dots and quantum rods, etc. Hereinafter, the display panel DP is described as an organic light-emitting display panel.

The display panel DP includes a base substrate BS, a circuit element layer DP-CL, a light-emitting element layer DP-OL, and an encapsulation layer ECL sequentially stacked along the third direction DR3.

The base substrate BS may be a rigid substrate or a flexible substrate capable of being bent, folded, or rolled. For example, the base substrate BS may be a glass substrate, a metal substrate, a polymer substrate, or the like. The base substrate BS may provide a base surface on which the circuit element layer DP-CL is disposed.

The base substrate BS may include an inorganic layer, an organic layer, and/or a composite material layer. The base substrate BS may have a single-layer or multi-layer structure. For example, the base substrate BS having a multi-layer structure may include synthetic resin layers and a multi-layer or single-layer inorganic layer disposed between the synthetic resin layers. The synthetic resin layer may include, but is not limited to, an acrylic-based resin, a methacrylic-based resin, polyisoprene, a vinyl-based resin, an epoxy-based resin, a urethane-based resin, a cellulose-based resin, a siloxane-based resin, a polyamide-based resin, or a perylene-based resin, but the material of the synthetic resin layer is not limited thereto.

The circuit element layer DP-CL may be disposed on the base substrate BS. The circuit element layer DP-CL may include at least one insulating layer, a semiconductor pattern, and a conductive pattern. The insulating layer, the semiconductor pattern, and the conductive pattern included in the circuit element layer DP-CL may form driving elements such as a transistor, signal lines, and pads.

The light-emitting element layer DP-OL may be disposed on the circuit element layer DP-CL. The light-emitting element layer DP-OL may include light-emitting elements each emitting light. For example, the light-emitting elements may include, but are not limited to, an organic light-emitting element, an inorganic light-emitting element, a micro LED, a nano LED, or the like. The light-emitting elements of the light-emitting element layer DP-OL may be electrically connected to the driving elements of the circuit element layer DP-CL and emit light according to an electrical signal provided by the driving elements.

The encapsulation layer ECL may be disposed on the light-emitting element layer DP-OL to seal the light-emitting elements. The encapsulation layer ECL may include at least one thin film for improving the optical efficiency of the light-emitting element layer DP-OL or protecting the light-emitting element layer DP-OL. For example, the encapsulation layer ECL may include at least one of an inorganic film or an organic film. The inorganic film of the encapsulation layer ECL may protect the light-emitting elements from moisture/oxygen. The organic film of the encapsulation layer ECL may protect the light-emitting elements from foreign substances such as dust particles.

The input sensing unit ISP may sense an external input and provide an input signal including the information about the external input so which the display panel DP may display an image corresponding to the external input. The input sensing unit ISP may be driven in various ways such as a capacitive method, a resistive method, an infrared method, an acoustic wave method, and/or a pressure method. The driving method of the input sensing unit ISP is not limited to any one embodiment as long as it can sense an external input. In this non-limiting embodiment, the input sensing unit ISP is described as an input sensing panel driven by a capacitive method.

The input sensing unit ISP includes a base layer IL1, a first sensing conductive layer CL1, a first sensing insulating layer IL2, a second sensing conductive layer CL2, and a second sensing insulating layer IL3 sequentially stacked along the third direction DR3. The base layer IL1 of the input sensing unit ISP may be in contact with the encapsulation layer ECL. However, the embodiment of the inventive concept is not limited thereto, and at least one of the base layer IL1 or the second sensing insulating layer IL3 may be omitted.

Each of the first sensing conductive layer CL1 and the second sensing conductive layer CL2 may have a single-layer or multi-layer structure. The multi-layer conductive layer may include at least two of transparent conductive layers and metal layers. A multi-layer conductive layer may include metal layers including different metals. The transparent conductive layer may include at least one of indium tin oxide (ITO), indium zinc oxide IZO, zinc oxide ZnO, indium tin zinc oxide ITZO, PEDOT, metal nanowire, or graphene. The metal layer may include at least one of molybdenum, silver, titanium, copper, aluminum, or an alloy thereof. For example, each of the first sensing conductive layer CL1 and the second sensing conductive layer CL2 may have a two-layer structure, such as ITO and copper, or without being limited thereto, a three-layer structure, such as titanium, aluminum, and titanium.

Each of the first sensing conductive layer CL1 and the second sensing conductive layer CL2 may include sensing conductive patterns. The sensing conductive patterns of the first sensing conductive layer CL1 and the second sensing conductive layer CL2 may form sensing electrodes to constitute the input sensing unit ISP and sensing lines connected thereto.

Each of the base layer IL1, the first sensing insulating layer IL2, and the second sensing insulating layer IL3 may include at least one of an inorganic film or an organic film. For example, the inorganic film may include at least any one of aluminum oxide, titanium oxide, silicon oxide, silicon oxynitride, zirconium oxide, or hafnium oxide, and the organic film may include at least one of an acrylic-based resin, a methacrylic-based resin, polyisoprene, a vinyl-based resin, an epoxy-based resin, a urethane-based resin, a cellulose-based resin, a siloxane-based resin, a polyimide-based resin, a polyamide-based resin, or a perylene-based resin. However, the materials of the inorganic film and the organic film are not limited to the above examples. In an embodiment of the inventive concept, the base layer IL1 may include an inorganic film, and the first sensing insulating layer IL2 and the second sensing insulating layer IL3 may include an organic film, but the embodiment of the inventive concept is not limited thereto.

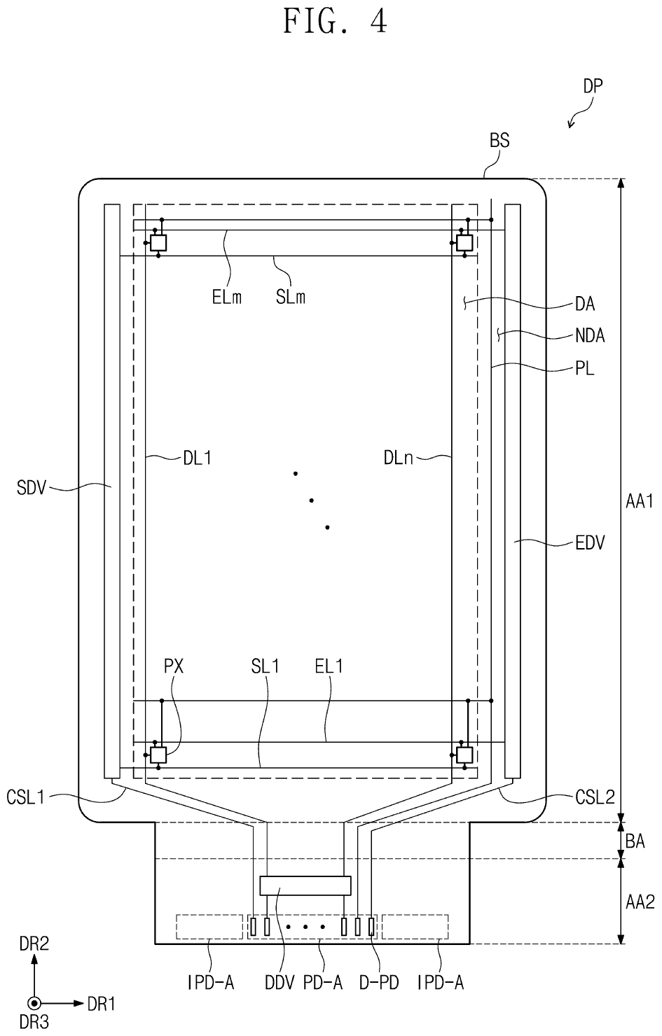

FIG. 4 is a plan view of a display panel DP according to an embodiment of the inventive concept.

Referring to FIG. 4, the display panel DP includes a base substrate BS, pixels PX, signal lines SL1 to SLm, DL1 to DLn, EL1 to ELm, CSL1, CSL2, and PL electrically connected to the pixels PX, a scan driver SDV, a light-emitting driver EDV, a data driver DDV, and display pads D-PD.

The base substrate BS may provide a base surface on which electrical elements, lines, etc. of the display panel DP are disposed. The base substrate BS may include a first base region AA1, a bending region BA, and a second base region AA2, which are distinguished from each other in the second direction DR2. The bending region BA may extend from the first base region AA1 in the second direction DR2. The second base region AA2 may extend from the bending region BA in the second direction DR2. Accordingly, the first base region AA1 and the second base region AA2 may be spaced apart from each other with the bending region BA interposed therebetween.

The first base region AA1 may include a display region DA. The display region DA may be a region in which the light-emitting elements of the pixels PX are disposed. Accordingly, the pixels PX may display an image through the display region DA. The display region DA may correspond to the active region AA (see FIG. 2) of the display module DM (see FIG. 2) and overlap the transmission region TA (see FIG. 2) of the window WM (see FIG. 2).

The remaining first base region AA1 excluding the display region DA, the bending region BA, and the second base region AA2 may be defined as a non-display region NDA. The non-display region NDA may be adjacent to the display region DA and be a region in which no image is displayed. The non-display region NDA may surround the display region DA. In the non-display region NDA, the scan driver SDV, the light-emitting driver EDV, and the data driver DDV for driving the pixels PX, along with the display pads D-PD electrically connected to the signal lines SL1 to SLm, DL1 to DLn, EL1 to ELm, CSL1, CSL2, and PL, may be disposed. The signal lines SL1 to SLm, DL1 to DLn, EL1 to ELm, CSL1, CSL2, and PL electrically connected to the pixels PX may extend and be disposed in the non-display region NDA.

The bending region BA may be bent with respect to a bending axis extending in the first direction DR1. That is, the bending region BA may be bent toward the rear surface of the display panel DP corresponding to the first base region AA1. In a plan view, the second base region AA2 extending from one side of the bending region BA may overlap the first base region AA1 as the bending region BA is bent. That is, the second base region AA2 may be disposed on the rear surface of the display panel DP corresponding to the first base region AA1.

In the first direction DR1, the width of each of the bending region BA and the second base region AA2 may be smaller than the width of the first base region AA1. Since the bending region BA has a width smaller than which of the first base region AA1 in a direction parallel to the bending axis, the bending region BA may be easily bent. However, this is illustrated as an example, and at least one of the widths of the bending region BA and the second base region AA2 in the first direction DR1 may be equal to the width of the first base region AA1, and the inventive concept is not limited to any one embodiment.

The second base region AA2, due to the bending of the bending region BA, may be located below the first base region AA1 and provided as a flat region. The second base region AA2 may be a region in which the data driver DDV and signal lines extending toward the display pads D-PD via the bending region BA among the signal lines SL1 to SLm, DL1 to DLn, EL1 to ELm, CSL1, CSL2, and PL are disposed.

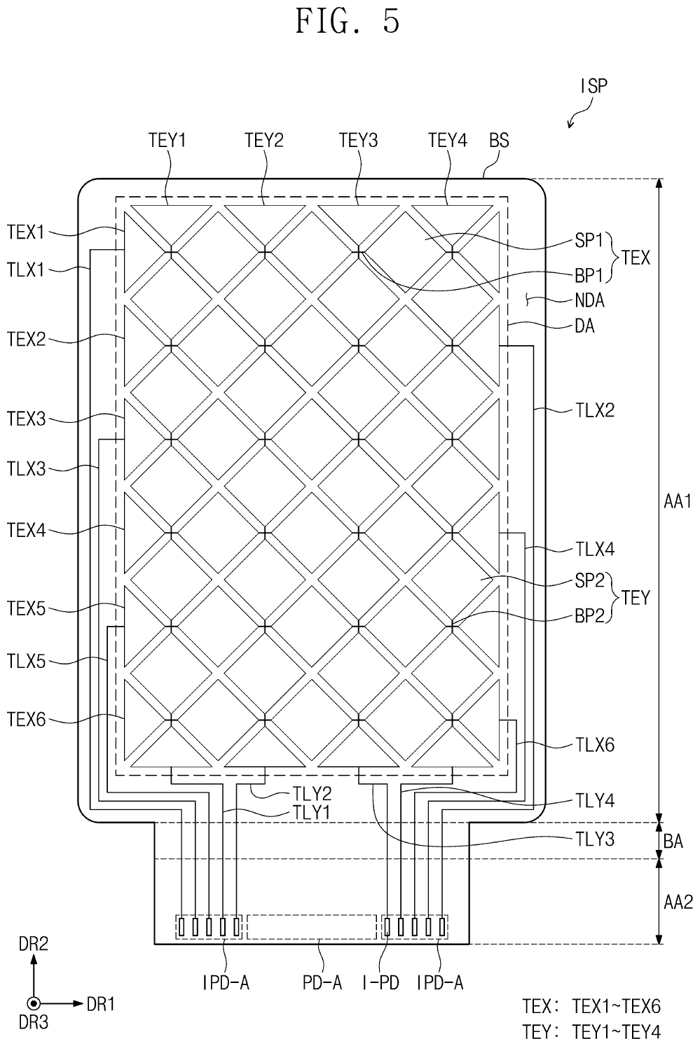

A region in which the display pads D-PD are disposed and a region in which sensing pads I-PD (see FIG. 5) to be described later are disposed may be respectively defined as a display pad region PD-A and a sensing pad region IPD-A. FIG. 4 exemplarily illustrates which the display pad region PD-A and the sensing pad region IPD-A are divided in the first direction DR1. For example, the sensing pad region IPD-A may be provided adjacent to both sides of the second base region AA2 in the first direction DR1, and the display pad region PD-A may be provided in a central portion. However, the embodiment of the inventive concept is not necessarily limited thereto, and the placement positions of the display pads D-PD and the sensing pads I-PD (see FIG. 5) may be changed in various ways.

The flexible circuit board FCB (see FIG. 2) may be disposed on the second base region AA2, in which the display pads D-PD and the sensing pads I-PD (see FIG. 5) are disposed, and may be electrically connected to the display pads D-PD and the sensing pads I-PD (see FIG. 5). The flexible circuit board FCB (see FIG. 2) disposed adjacent to the lower end of the second base region AA2 may be positioned on the rear surface of the display panel DP by the bending of the bending region BA. Since the second base region AA2 and the flexible circuit board FCB (see FIG. 2) are positioned below the first base region AA1 on the front surface of the electronic apparatus EA (see FIG. 2), the area of the bezel region of the electronic apparatus EA (see FIG. 2) may be reduced.

Each of the pixels PX may include a pixel driving circuit composed of transistors (e.g., a switching transistor, a driving transistor, etc.) and at least one capacitor, and a light-emitting element electrically connected to the pixel driving circuit. The pixels PX may generate light in response to an electrical signal applied to each of the pixels PX and display an image through the display region DA. According to an embodiment of the inventive concept, some of the pixels PX may include a transistor disposed in the non-display region NDA, but the inventive concept is not limited to any one embodiment.

The scan driver SDV and the light-emitting driver EDV may be disposed in the non-display region NDA corresponding to the first base region AA1. The data driver DDV may be disposed in the non-display region NDA corresponding to the second base region AA2. In an embodiment of the inventive concept, the data driver DDV may be provided in the form of an integrated circuit chip mounted in the non-display region NDA of the display panel DP. Without being limited thereto, however, the data driver DDV may be mounted on the flexible circuit board FCB (see FIG. 2).

The signal lines SL1 to SLm, DL1 to DLn, EL1 to ELm, CSL1, CSL2, and PL may include scan lines SL1 to SLm, data lines DL1 to DLn, light-emitting lines EL1 to ELm, first and second control lines CSL1 and CSL2, and a power line PL, wherein m and n are natural numbers.

The data lines DL1 to DLn may be insulated from and extend across the scan lines SL1 to SLm and the light-emitting lines EL1 to ELm. For example, the scan lines SL1 to SLm may extend in the first direction DR1 and be electrically connected to the scan driver SDV. The data lines DL1 to DLn may extend in the second direction DR2 and be electrically connected to the data driver DDV. The light-emitting lines EL1 to ELm may extend in the first direction DR1 and be electrically connected to the light-emitting driver EDV.

The power line PL may include a portion extending in the first direction DR1 and a portion extending in the second direction DR2. The portion of the power line PL extending in the first direction DR1 and the portion thereof extending in the second direction DR2 may be disposed on different layers or may be integrally disposed on a same layer. The portion of the power line PL extending in the first direction DR1 may be electrically connected to the pixels PX and the portion extending in the second direction DR2. The portion of the power line PL extending in the second direction DR2 may be disposed in the non-display region NDA and electrically connected to the display pads D-PD from the first base region AA1 via the bending region BA and the second base region AA2. The power line PL may provide a first voltage to the pixels PX.

The first control line CSL1 may be electrically connected to the scan driver SDV and extend toward the lower end of the second base region AA2 via the bending region BA. The second control line CSL2 may be electrically connected to the light-emitting driver EDV and extend toward the lower end of the second base region AA2 via the bending region BA.

The display pads D-PD may be disposed adjacent to the lower end of the second base region AA2. In the second base region AA2, the display pads D-PD may be disposed closer to the lower end of the base substrate BS than the data driver DDV. The display pads D-PD may be spaced apart from each other along the first direction DR1. Each of the power line PL, the first control line CSL1, and the second control line CSL2 may be electrically connected to a corresponding display pad D-PD among the display pads D-PD. Each of the data lines DL1 to DLn may be electrically connected to a corresponding display pad D-PD among the display pads D-PD via the data driver DDV.

The display pads D-PD may be electrically connected to the flexible circuit board FCB (see FIG. 2) through an adhesive layer, and an electrical signal provided from the flexible circuit board FCB (see FIG. 2) may be transmitted to the display panel DP via the display pads D-PD. However, the connection method of the display pads D-PD and the flexible circuit board FCB (see FIG. 2) is not limited thereto.

The scan driver SDV may generate scan signals in response to a scan control signal. The scan signals may be applied to the pixels PX through the scan lines SL1 to SLm. The data driver DDV may generate data voltages corresponding to image signals in response to a data control signal. The data voltages may be applied to the pixels PX through the data lines DL1 to DLn. The light-emitting driver EDV may generate light-emitting signals in response to a light-emitting control signal. The light-emitting signals may be applied to the pixels PX through the light-emitting lines EL1 to ELm.

The pixels PX may receive data voltages in response to the scan signals. The pixels PX may generate an image by emitting light with luminance corresponding to the data voltages in response to the light-emitting signals. The light-emitting time of the pixels PX may be controlled by the light-emitting signals.

FIG. 5 is a plan view of an input sensing unit ISP according to an embodiment of the inventive concept. For the convenience of explanation, FIG. 5 briefly illustrates the components of the input sensing unit ISP disposed on the base substrate BS described above.

In an embodiment of the inventive concept, the input sensing unit ISP may be driven by a mutual capacitance type. Referring to FIG. 5, the input sensing unit ISP may include first sensing electrodes TEX: TEX1 to TEX6, second sensing electrodes TEY: TEY1 to TEY4, first sensing lines TLX1 to TLX6, second sensing lines TLY1 to TLY4, and sensing pads I-PD. However, the embodiment of the inventive concept is not limited thereto, and the input sensing unit ISP may be driven by a self-capacitance type.

Each of the first sensing electrodes TEX may extend along the first direction DR1, and the first sensing electrodes TEX may be arranged along the second direction DR2. FIG. 5 exemplarily illustrates six first sensing electrodes TEX1 to TEX6. However, the number of the first sensing electrodes TEX included in the input sensing unit ISP is not limited thereto. One first sensing electrode TEX may include first sensing patterns SP1 arranged along the first direction DR1 and first connection patterns BP1 connecting them to each other.

Each of the second sensing electrodes TEY may extend along the second direction DR2, and the second sensing electrodes TEY may be arranged along the first direction DR1. FIG. 5 exemplarily illustrates four second sensing electrodes TEY1 to TEX4. However, the number of the second sensing electrodes TEY included in the input sensing unit ISP is not limited thereto. One second sensing electrode TEY may include second sensing patterns SP2 arranged along the second direction DR2 and second connection patterns BP2 connecting them to each other.

The first sensing electrodes TEX and the second sensing electrodes TEY may be electrically insulated from each other. The input sensing unit ISP may sense an external input through a change in capacitance between the first sensing electrodes TEX and the second sensing electrodes TEY. The first sensing electrodes TEX and the second sensing electrodes TEY may be disposed in a region corresponding to the display region DA of the base substrate BS. Accordingly, the electronic apparatus EA (see FIG. 1) may display an image through the display region DA and also sense an external input applied to the display region DA.

The first sensing lines TLX1 to TLX6 may be disposed in the non-display region NDA and electrically connected to the first sensing electrodes TEX1 to TEX6, respectively. Some of the first sensing lines TLX1 to TLX6 may be disposed on the left side of the non-display region NDA, and the rest may be disposed on the right side thereof. For example, the first sensing lines TLX1, TLX3, and TLX5 connected to the first sensing electrodes TEX1, TEX3, and TEX5 disposed in odd-numbered rows may be respectively connected to the left sides of the first sensing electrodes TEX1, TEX3, and TEX5, and the first sensing lines TLX2, TLX4, and TLX6 connected to the first sensing electrodes TEX2, TEX4, and TEX6 disposed in even-numbered rows may be respectively connected to the right sides of the first sensing electrodes TEX2, TEX4, and TEX6. However, the placement of the first sensing lines TLX1 to TLX6 is not limited thereto, and all of the first sensing lines TLX1 to TLX6 may be disposed on the left side of the non-display region NDA, or on the right side thereof.

Each of the first sensing lines TLX1 to TLX6 may extend from the first base region AA1 to the second base region AA2 via the bending region BA. The first sensing lines TLX1 to TLX6 may be respectively electrically connected to the sensing pads I-PD disposed in the second base region AA2.

The second sensing lines TLY1 to TLY4 may be disposed in the non-display region NDA and electrically connected to the second sensing electrodes TEY1 to TEY4, respectively. Some of the second sensing lines TLY1 to TLY4 may be disposed adjacent to the left side of the non-display region NDA, and the rest may be disposed adjacent to the right side thereof. For example, in the first direction DR1, the second sensing lines TLY1 and TLY2 electrically connected to the second sensing electrodes TEY1 and TEY2 disposed on the left side of the second sensing electrodes TEY1 to TEY4 may be disposed adjacent to the left side of the first base region AA1, and the second sensing lines TLY3 and TLY4 electrically connected to the second sensing electrodes TEY3 and TEY4 disposed on the right side thereof may be disposed adjacent to the right side of the first base region AA1. However, the placement of the second sensing lines TLY1 to TLY4 is not limited thereto.

Each of the second sensing lines TLY1 to TLY4 may extend from a region adjacent to the lower end of the first base region AA1 toward the second base region AA2 via the bending region BA. The second sensing lines TLY1 to TLY4 may be respectively electrically connected to the sensing pads I-PD disposed in the second base region AA2.

In the first direction DR1, some of the sensing pads I-PD may be disposed in a region adjacent to the left side of the second base region AA2, and the rest may be disposed in a region adjacent to the right side thereof. For example, the sensing pads I-PD may be divided into two groups spaced apart from each other with the display pad region PD-A interposed therebetween. However, the placement of the sensing pads I-PD is not limited thereto.

The sensing pads I-PD may be disposed at the same layer as the display pads D-PD (see FIG. 4). The sensing pads I-PD may be disposed on a different layer from the first and second sensing lines TLX1 to TLX6 and TLY1 to TLY4 and connected thereto through a contact hole. Without being limited thereto, however, the sensing pads I-PD may also be disposed on a different layer from the display pads D-PD (see FIG. 4). For example, the sensing pads I-PD may be integrally formed on the same layer as the first and second sensing lines TLX1 to TLX6 and TLY1 to TLY4.

The first and second sensing lines TLX1 to TLX6 and TLY1 to TLY4 may be disposed above the components of the display panel DP (see FIG. 4) in a region corresponding to the non-display region NDA of the base substrate BS. Accordingly, the first and second sensing lines TLX1 to TLX6 and TLY1 to TLY4 may overlap the components of the display panel DP (see FIG. 4) in the bending region BA and the second base region AA2.

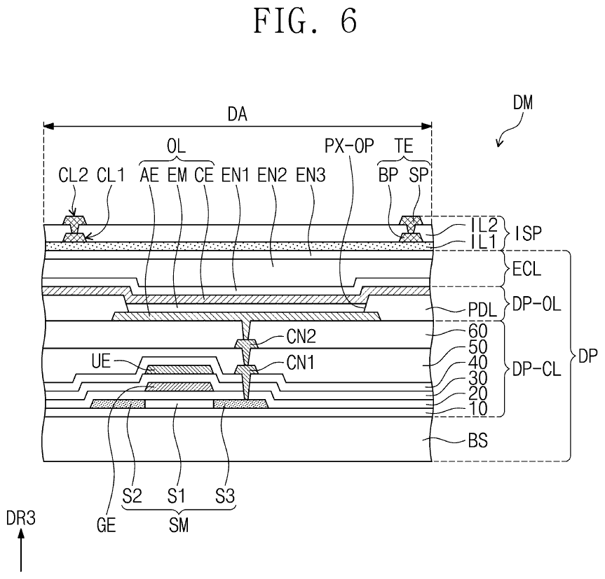

FIG. 6 is a cross-sectional view of the display module DM according to an embodiment of the inventive concept. FIG. 6 exemplarily illustrates a cross section of a pixel PX (see FIG. 4) disposed in the display region DA.

Referring to FIG. 6, the display module DM may include a display panel DP and an input sensing unit ISP disposed on the display panel DP. The aforementioned description may be equally applied to each component thereof.

As described above in FIG. 3, the display panel DP may include a base substrate BS, a circuit element layer DP-CL, a light-emitting element layer DP-OL, and an encapsulation layer ECL.

The base substrate BS may have insulating properties and provide a base surface on which the components of the display module DM are disposed. The base substrate BS may have flexibility so as to be bendable. As described above, the base substrate BS may include a first base region AA1 (see FIG. 4), a bending region BA (see FIG. 4), and a second base region AA2 (see FIG. 4), and the bending region BA (see FIG. 4) of the base substrate BS may be bent at a predetermined curvature.

The circuit element layer DP-CL may include insulating layers 10, 20, 30, 40, 50, and 60 (collectively referred to as layers 10 to 60) disposed above the base substrate BS, a transistor TR of the pixel PX (see FIG. 4), an upper electrode UE, and connection electrodes CN1 and CN2. The insulating layers 10 to 60 may include first to sixth insulating layers 10 to 60 sequentially stacked along the thickness direction on the base substrate BS. However, the embodiment of the insulating layers 10 to 60 included in the circuit element layer DP-CL is not limited thereto and may be changed according to the configuration or manufacturing process of the circuit element layer DP-CL.

The first insulating layer 10 may be disposed on the base substrate BS. The first insulating layer 10 may be provided as a barrier layer and/or a buffer layer which prevents foreign substances from entering from the outside. The first insulating layer 10 may improve the bonding strength between the base substrate BS and the semiconductor pattern SM and/or the conductive pattern of the circuit element layer DP-CL. The first insulating layer 10 may be formed from an insulative material. For example, the first insulating layer may include at least one of a silicon oxide layer or a silicon nitride layer. In an embodiment of the inventive concept, the first insulating layer 10 may include silicon oxide layers and silicon nitride layers which are alternately stacked.

The pixel PX (see FIG. 4) may be disposed on the base substrate BS. The pixel PX (see FIG. 4) may be disposed to correspond to the display region DA. The pixel PX (see FIG. 4) may include a transistor TR and a light-emitting element OL.

The transistor TR may include a semiconductor pattern SM and a gate electrode GE. The semiconductor pattern SM may be disposed on the first insulating layer 10. The semiconductor pattern SM may include a channel S1, a source S2, and a drain S3. The semiconductor pattern SM may include a silicon semiconductor and may include a single-crystal silicon semiconductor, a polysilicon semiconductor, or an amorphous silicon semiconductor. Without being limited thereto, the semiconductor pattern SM may also include an oxide semiconductor. The semiconductor pattern SM according to an embodiment of the inventive concept may be formed of various materials as long as they have semiconductor properties, and the inventive concept is not limited to any one embodiment.

The semiconductor pattern SM may include a plurality of regions having different electrical properties depending on whether it is doped or reduced. For example, the semiconductor pattern SM may include a highly conductive region which is doped or formed by reduction of a metal oxide, and the highly conductive region may serve as a signal line or an electrode of the transistor TR. This may correspond to the source S2 and the drain S3 of the transistor TR. The semiconductor pattern SM may include a region which is undoped and has relatively low conductivity, and this may correspond to the channel S1 (or active) of the transistor TR.

The second insulating layer 20 may be disposed on the first insulating layer 10 to cover the semiconductor pattern SM. The gate electrode GE may be disposed on the second insulating layer 20. The second insulating layer 20 may be disposed between the semiconductor pattern SM of the transistor TR and the gate electrode GE. In a plan view, the gate electrode GE may overlap the channel S1 of the semiconductor pattern SM. The gate electrode GE may function as a mask in a process of doping the semiconductor pattern SM. The gate electrode GE may include, but is not limited to, molybdenum (Mo) having heat resistance, an alloy containing molybdenum, titanium (Ti), an alloy containing titanium, etc.

The structure of the transistor TR illustrated in FIG. 6 is exemplary, and the source S2 or the drain S3 of the transistor TR may be electrodes formed independently from the semiconductor pattern SM. In this case, the source S2 and the drain S3 may be in contact with the semiconductor pattern SM or connected to the semiconductor pattern SM by passing through an insulating layer. In addition, the gate electrode GE may be disposed below the semiconductor pattern SM. The transistor TR according to an embodiment of the inventive concept may be formed in various structures and is not limited to any one embodiment.

The second insulating layer 20 and the third to sixth insulating layers 30 to 60 to be described later may include at least one of an inorganic layer or an organic layer. For example, the inorganic layer may include, but is not limited to, aluminum oxide, titanium oxide, silicon oxide, silicon oxynitride, zirconium oxide, or hafnium oxide. The organic layer may include, but is not limited to, an acrylic-based resin, a methacrylic-based resin, polyisoprene, a vinyl-based resin, an epoxy-based resin, a urethane-based resin, a cellulose-based resin, a siloxane-based resin, a polyamide-based resin, or a perylene-based resin.

The third insulating layer 30 may be disposed on the second insulating layer 20 and cover the gate electrode GE. The upper electrode UE may be disposed on the third insulating layer 30. In a plan view, the upper electrode UE may overlap the gate electrode GE, and the gate electrode GE and the upper electrode UE which overlap each other may form a capacitor.

The fourth insulating layer 40 may be disposed on the third insulating layer 30 and cover the upper electrode UE. The connection electrodes CN1 and CN2 may include a first connection electrode CN1 and a second connection electrode CN2. The first connection electrode CN1 may be disposed on the fourth insulating layer 40. The fifth insulating layer 50 may be disposed on the fourth insulating layer 40 and cover the first connection electrode CN1. The second connection electrode CN2 may be disposed on the fifth insulating layer 50. The sixth insulating layer 60 may be disposed on the fifth insulating layer 50 and cover the second connection electrode CN2. In an embodiment of the inventive concept, at least one of the fifth insulating layer 50 or the sixth insulating layer 60 may include an organic layer, cover a step difference between the components disposed thereunder, and provide a flat upper surface.

The first connection electrode CN1 may be electrically connected to the semiconductor pattern SM through a contact hole passing through the second to fourth insulating layers 20 to 40. The second connection electrode CN2 may be electrically connected to the first connection electrode CN1 through a contact hole passing through the fifth insulating layer 50.

Each of the first connection electrode CN1 and the second connection electrode CN2 may include a conductive material. Each of the first connection electrode CN1 and the second connection electrode CN2 may include gold, silver, copper, aluminum, platinum, molybdenum, titanium, and alloys thereof. At least one of the first connection electrode CN1 or the second connection electrode CN2 may include multi-layer conductive layers. For example, at least one of the first connection electrode CN1 or the second connection electrode CN2 may have a three-layer structure of titanium/aluminum/titanium. However, the embodiment of the inventive concept is not limited thereto.

According to an embodiment of the circuit element layer DP-CL, at least one of the first connection electrode CN1 or the second connection electrode CN2 may be omitted. Alternatively, according to an embodiment of the circuit element layer DP-CL, an additional connection electrode connecting the transistor TR and the light-emitting element OL to each other may be further disposed. Depending on the number of the insulating layers disposed between the light-emitting element OL and the transistor TR, the electrical connection method between the light-emitting element OL and the transistor TR may be variously changed, and the inventive concept is not limited to any one embodiment.

The light-emitting element layer DP-OL may include a light-emitting element OL and a pixel defining film PDL. The light-emitting element OL and the pixel defining film PDL may be disposed on the sixth insulating layer 60. The light-emitting element OL may include a first electrode AE, a light-emitting layer EM, and a second electrode CE.

The first electrode AE may be electrically connected to the second connection electrode CN2 through a contact hole passing through the sixth insulating layer 60. The first electrode AE may be electrically connected to the transistor TR through the first and second connection electrodes CN1 and CN2.

A pixel opening PX-OP exposing at least a portion of the first electrode AE may be defined in the pixel defining film PDL. One region of the first electrode AE exposed from the pixel defining film PDL may correspond to a light-emitting region. The pixel defining film PDL may include an inorganic layer, an organic layer, or a composite material layer. According to an embodiment of the inventive concept, the pixel defining film PDL may further include a black pigment or a black dye.

The light-emitting layer EM may be disposed on the first electrode AE. The light-emitting layer EM may provide light of a predetermined color. The light-emitting layer EM may be disposed to correspond to the pixel opening PX-OP defined in the pixel defining film PDL. The light-emitting element OL and the pixel opening PX-OP may be provided in plurality, and the light-emitting layers EM of the light-emitting elements OL may be disposed to correspond to the pixel openings PX-OP respectively and provided in a pattern form in which they are spaced apart from each other. Without being limited thereto, however, the light-emitting layers EM of the light-emitting elements OL may be formed as an integrated common layer.

The second electrode CE may be disposed on the light-emitting layer EM and the pixel defining film PDL. The second electrode CE may be provided as a common electrode disposed commonly in the pixels PX (see FIG. 4).

The light-emitting element OL may further include at least one of a hole control region disposed between the first electrode AE and the light-emitting layer EM or an electron control region disposed between the light-emitting layer EM and the second electrode CE. The hole control region may include at least one of a hole generation layer, a hole transport layer, or an electron blocking layer, and the electron control region may include at least one of an electron generation layer, an electron transport layer, or a hole blocking layer.

The encapsulation layer ECL may be disposed on the light-emitting element layer DP-OL. The encapsulation layer ECL may be disposed on the light-emitting element OL and the pixel defining film PDL to seal the light-emitting element OL. The encapsulation layer ECL may include at least one of an inorganic film or an organic film. In this embodiment, the encapsulation layer ECL may include a first inorganic film EN1, a second inorganic film EN3, and an organic film EN2 disposed between the first and second inorganic films EN1 and EN3. However, the components of the encapsulating layer ECL are not limited thereto as long as they can seal the light-emitting element OL.

The first inorganic film EN1 may be disposed on the second electrode CE, and the organic film EN2 and the second inorganic film EN3 may be sequentially disposed on the first inorganic film EN1 in the thickness direction of the display panel DP. The first and second inorganic films EN1 and EN3 may protect the light-emitting element OL from moisture or oxygen which enters from the outside. For example, each of the first and second inorganic films EN1 and EN3 may formed from a material including, but not limited to, f silicon nitride, silicon oxynitride, silicon oxide, titanium oxide, and aluminum oxide. However, the material of the first and second inorganic films EN1 and EN3 is not limited to the above examples. The organic film EN2 may prevent foreign substances from entering the light-emitting element OL and cover the step differences of the components disposed below the organic film EN2. For example, the organic film EN2 may include an acrylic-based organic material. However, the material of the organic film EN2 is not limited to the above example.

The input sensing unit ISP may be disposed on the display panel DP. The input sensing unit ISP may include a base layer IL1, a first sensing insulating layer IL2, a first sensing conductive layer CL1, and a second sensing conductive layer CL2. The input sensing unit ISP may further include a second sensing insulating layer IL3 (see FIG. 3) as illustrated in FIG. 3. The aforementioned descriptions may be equally applied to each component thereof.

The base layer IL1 may be in contact with the uppermost layer of the encapsulation layer ECL. For example, the base layer IL1 may be in contact with the second inorganic film EN3 of the encapsulation layer ECL. The base layer IL1 of the input sensing unit ISP may be formed directly on a base surface provided by the encapsulation layer ECL. Without being limited thereto, however, according to an embodiment of the inventive concept, the base layer IL1 may be omitted, and in this case, the first sensing conductive layer CL1 of the input sensing unit ISP may be in contact with the encapsulation layer ECL.

The first sensing conductive layer CL1 may be disposed on the base layer IL1, and the second sensing conductive layer CL2 may be disposed on the first sensing insulating layer IL2. The first sensing conductive layer CL1 and the second sensing conductive layer CL2 may form a sensing electrode TE. The sensing electrode TE may correspond to any one of the first and second sensing electrodes TEX and TEY (see FIG. 5) described above. For example, the first sensing conductive layer CL1 may include a connection pattern BP of the sensing electrode TE, and the second sensing conductive layer CL2 may include a sensing pattern SP of the sensing electrode TE. Without being limited thereto, however, the first sensing conductive layer CL1 may include a sensing pattern SP, and the second sensing conductive layer CL2 may include a connection pattern BP.

The connection pattern BP may correspond to the first connection pattern BP1 (see FIG. 5) or the second connection pattern BP2 (see FIG. 5) described above, and the sensing pattern SP may correspond to the first sensing pattern SP1 (see FIG. 5) or the second sensing pattern SP2 (see FIG. 5) described above. The connection pattern BP may be disposed on a different layer from the sensing pattern SP and connected to the sensing pattern SP through a contact hole passing through the first sensing insulating layer IL2. Without being limited thereto, however, the connection pattern BP and the sensing pattern SP may be disposed at the same layer as each other and formed integrally.

The sensing electrode TE may be a mesh-shaped pattern and disposed to correspond to a region in which the pixel defining film PDL is disposed. Without being limited thereto, however, the sensing electrode TE may be provided as a single-shaped pattern overlapping the light-emitting element OL, and in this case, the sensing electrode TE may include a transparent conductive material.

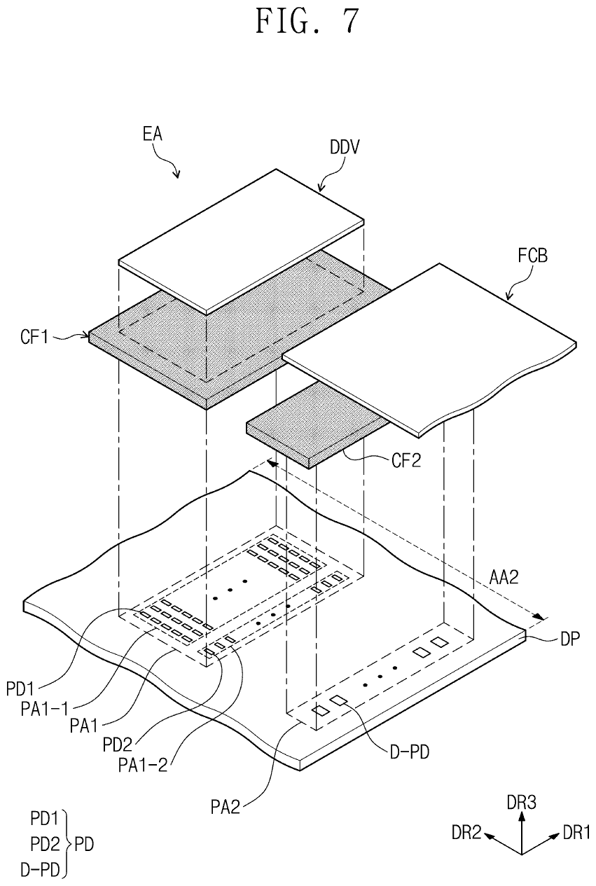

FIG. 7 is a perspective view of the electronic apparatus EA according to an embodiment of the inventive concept. FIG. 7 briefly illustrates some components of the electronic apparatus EA disposed to correspond to the second base region AA2.

The second base region AA2 corresponds to a partial region of the non-display region NDA (see FIG. 4). As illustrated in FIG. 7, a region of the non-display region NDA or the second base region AA2, to which the data driver DDV is bonded, may be defined as a first pad region PA1, and a region to which the flexible circuit board FCB is bonded may be defined as a second pad region PA2.

The data driver DDV may be bonded to the first pad region PA1 by a first adhesive layer CF1, and the flexible circuit board FCB may be bonded to the second pad region PA2 by a second adhesive layer CF2. Each of the first adhesive layer CF1 and the second adhesive layer CF2 may include a synthetic resin having adhesive properties. Each of the first adhesive layer CF1 and the second adhesive layer CF2 may be a non-conductive film NCF. For example, each of the first adhesive layer CF1 and the second adhesive layer CF2 may be an adhesive resin which does not include conductive particles.

Without being limited thereto, however, in an embodiment of the inventive concept, any one of the first adhesive layer CF1 and the second adhesive layer CF2 may be omitted. For example, the data driver DDV and the flexible circuit board FCB may be respectively bonded to the first pad region PA1 and the second pad region PA2 by ultrasonic bonding.

The display panel DP may include a plurality of pads PD. The plurality of pads PD may include first signal pads PD1, second signal pads PD2, and display pads D-PD. The first signal pads PD1, the second signal pads PD2, and the display pads D-PD may be disposed in a signal transmission path.

The first signal pads PD1 may be disposed to correspond to the output pads of the data driver DDV and may be input pads which receive signals from the data driver DDV. The second signal pads PD2 may be disposed to correspond to the input pads of the data driver DDV and may be output pads which output signals to the data driver DDV. The display pads D-PD may be panel input pads which receive signals from the flexible circuit board FCB.

Each of the first signal pads PD1 may be electrically connected to the pixels PX (see FIG. 4) of the display panel DP through a signal line and transmit signals to and receive signals from the pixels PX (see FIG. 4). Each of the second signal pads PD2 may be electrically connected to a corresponding display pad D-PD among the display pads D-PD through a signal line, and the display pads D-PD and the second signal pads PD2 which are electrically connected to each other may transmit and receive signals.

The first pad region PA1 may include a first sub-pad region PA1-1 and a second sub-pad region PA1-2. The first sub-pad region PA1-1 may be defined as a region in which the first signal pads PD1 are disposed. The second sub-pad region PA1-2 may be defined as a region in which the second signal pads PD2 are disposed.

The first signal pads PD1 may be arranged along the first direction DR1 and the second direction DR2 within the first sub-pad region PA1-1. Among the first signal pads PD1, the first signal pads PD1 arranged along the first direction DR1 may be defined as a pad row. FIG. 7 exemplarily illustrates which five pad rows are arranged along the second direction DR2. The placement of the first signal pads PD1 is not limited thereto.

The second signal pads PD2 may be arranged along the first direction DR1 within the second sub-pad region PA1-2. The second signal pads PD2 may be disposed in one pad row. However, the placement of the second signal pads PD2 is not limited thereto.

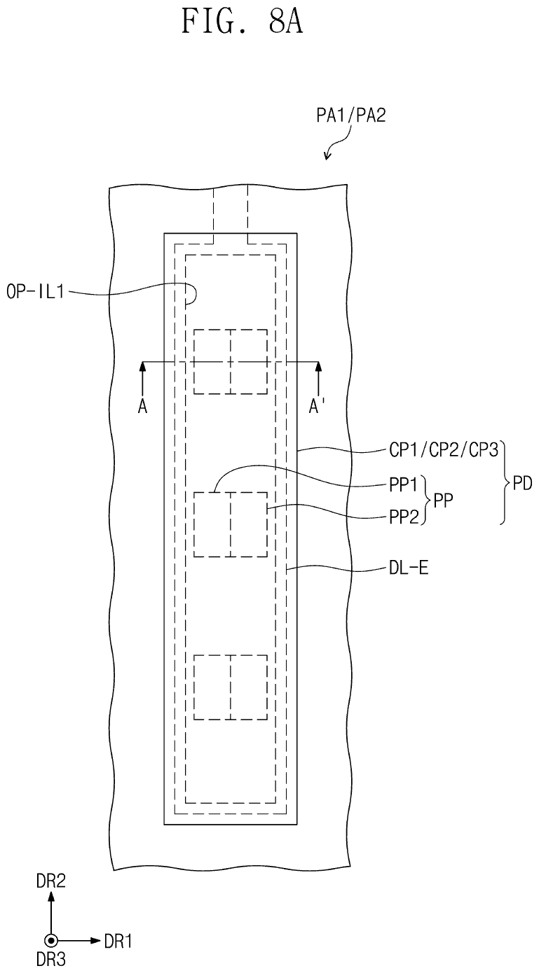

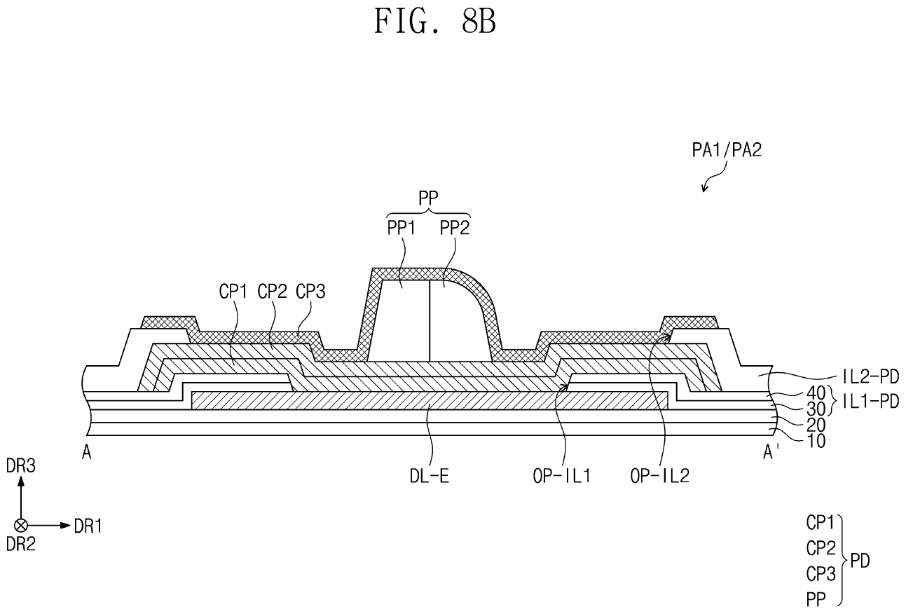

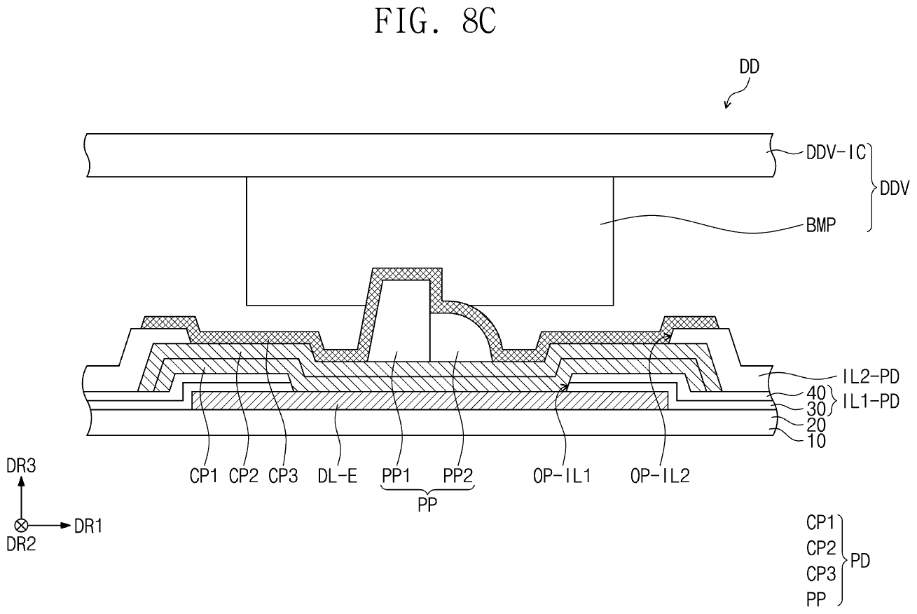

FIG. 8A is a plan view of a pad region PA1 or PA2 according to an embodiment of the inventive concept. FIG. 8B is a cross-sectional view of the pad region PA1 or PA2 according to an embodiment of the inventive concept. FIG. 8C is a cross-sectional view illustrating a bonding structure of a display device DD according to an embodiment of the inventive concept.

FIG. 8A is an enlarged schematic plan view illustrating a portion in which one signal pad PD is disposed in the pad region PA1 or PA2 according to an embodiment of the inventive concept. FIG. 8B is a cross-sectional view of the pad region PA1 or PA2 corresponding to line A-A′ of FIG. 8A. FIG. 8C is a cross-sectional view illustrating a bonding structure of a display device according to an embodiment of the inventive concept.

The signal pad PD illustrated in FIGS. 8A to 8C may be any one of the first signal pad PD1, the second signal pad PD2, and the display pad D-PD described with reference to FIG. 7. In addition, the data line DL1 to DLn (see FIG. 4) including an end portion DL-E is illustrated as an example of the signal line, but the embodiment of the inventive concept is not limited thereto. The signal line may be another signal line, other than the data line DL1 to DLn (see FIG. 4).

Hereinafter, the pad region PA1 or PA2 will be described with a focus on the first sub-pad region PA1-1 (see FIG. 7) in which the data line DL1 to DLn (see FIG. 4) is disposed. The description of the first sub pad region PA1-1 (see FIG. 7) may be equally applied to the second sub pad region PA1-2, except which a connection signal line is disposed instead of the data line DL1 to DLn (see FIG. 4).

Referring to FIGS. 8A and 8B, the signal pad PD may include a first conductive pattern CP1, a second conductive pattern CP2, a third conductive pattern CP3, and at least one insulating pattern PP. FIG. 8A exemplarily illustrates a structure in which all of the first conductive pattern CP1, the second conductive pattern CP2, and the third conductive pattern CP3 are disposed in the same location and have the same area as each other. The signal pad PD may further include pad insulating layers IL1-PD and IL2-PD. For example, the signal pad PD may further include a first pad insulating layer IL1-PD and a second pad insulating layer IL2-PD. For the convenience of explanation, the first and second pad insulating layers IL1-PD and IL2-PD are omitted in the plan view of FIG. 8A, and only a first insulating layer opening OP-IL1 defined in the first pad insulating layer IL1-PD is illustrated.

The end portion DL-E of the data line may be disposed in the pad region PA1 or PA2. In this specification, the end portion DL-E of the data line may be referred to as a portion of the signal line.

In a plan view, the end portion DL-E of the data line may have a shape extending in the second direction DR2. That is, the end portion DL-E may have a length or width in the second direction DR2 greater than a length or width in the first direction DR1. The end portion DL-E of the data line may be disposed at the same layer as the gate electrode GE (see FIG. 6) of the transistor TR (see FIG. 6) disposed in the aforementioned display region DA (see FIG. 6). For example, the end portion DL-E of the data line may be disposed on the second insulating layer 20 (see FIG. 6). The end portion DL-E of the data line may include the same material as the gate electrode GE (see FIG. 6). For example, the end portion DL-E of the data line may include molybdenum (Mo), an alloy containing molybdenum, titanium (Ti), an alloy containing titanium, or the like. The end portion DL-E of the data line may be formed in the same process step (e.g., a patterning step) as the gate electrode GE (see FIG. 6). The thickness of the end portion DL-E of the data line may be the same as the thickness of the gate electrode GE (see FIG. 6).

However, the position of the end portion DL-E is not limited thereto. The end portion DL-E may be disposed at the same layer, include the same material, and/or have the same stacked structure as the upper electrode UE illustrated in FIG. 6. Alternatively, some of the plurality of signal lines may be formed through the same process as the gate electrode GE (see FIG. 6), and the others may be formed through the same process as the upper electrode UE (see FIG. 6).

The data line DL1 to DLn (see FIG. 4) may be disposed on one layer and have an integrated shape, but the embodiment of the inventive concept is not limited thereto. One data line DL1 to DLn (see FIG. 4) may include a plurality of portions disposed on different layers.

The first conductive pattern CP1 may be disposed on the end portion DL-E of the data line. In a plan view, the first conductive pattern CP1 may overlap the end portion DL-E of the data line. In a plan view, the end portion DL-E of the data line may be disposed inside the first conductive pattern CP1, but the embodiment of the inventive concept is not limited thereto.

The first conductive pattern CP1 may be connected to the end portion DL-E of the data line DL1 to DLn (see FIG. 4) through the first insulating layer opening OP-IL1 defined in the first pad insulating layer IL1-PD. In this specification, insulating layers disposed between the end portion DL-E and the first conductive pattern CP1 may be defined as the first pad insulating layer IL1-PD. In this embodiment, the third and fourth insulating layers 30 and 40 may be defined as the first pad insulating layer IL1-PD. The stacked structure of the first pad insulating layer IL1-PD may be changed according to the stacked structure of the circuit element layer DP-CL (see FIG. 6). In an embodiment of the inventive concept, the first insulating layer opening OP-IL1 may be defined by a greater number of insulating layers or by a lesser number of insulating layers than the third and fourth insulating layers 30 and 40. The first conductive pattern CP1 and the end portion DL-E may be distinguished by the first pad insulating layer IL1-PD (for example, the third and fourth insulating layers 30 and 40) disposed therebetween.

The first conductive pattern CP1 may be disposed at the same layer as the first connection electrode CN1 (see FIG. 6) connected to the transistor TR (see FIG. 6) of the above-mentioned display region DA (see FIG. 6). For example, the first conductive pattern CP1 may be disposed on the fourth insulating layer 40. The first conductive pattern CP1 may include the same material as the first connection electrode CN1 (see FIG. 6). The first conductive pattern CP1 may be formed in the same process step as the first connection electrode CN1 (see FIG. 6). The first conductive pattern CP1 may have a single-layer or multi-layer structure and have the same stacked structure as the first connection electrode CN1 (see FIG. 6). For example, the first conductive pattern CP1 may have a three-layer structure of titanium/aluminum/titanium. The first conductive pattern CP1 may have the same thickness as the first connection electrode CN1 (see FIG. 6).

The second conductive pattern CP2 may be disposed on the first conductive pattern CP1. The second conductive pattern CP2 and the first conductive pattern CP1 may be distinguished by the presence of a boundary line on a cross section as they are formed in different process steps. The second conductive pattern CP2 may be in contact with the first conductive pattern CP1 and electrically connected thereto. In a plan view, the second conductive pattern CP2 may overlap the first conductive pattern CP1. In a plan view, the first conductive pattern CP1 may be disposed inside the second conductive pattern CP2. Without being limited thereto, however, for example, in a plan view the second conductive pattern CP2 may be disposed inside the first conductive pattern CP1, or they may be disposed in the same position.

The second conductive pattern CP2 may be disposed at the same layer as the second connection electrode CN2 (see FIG. 6) connected to the first connection electrode CN1 (see FIG. 6) of the aforementioned display region DA (see FIG. 6). The second conductive pattern CP2 may include the same material as the second connection electrode CN2 (see FIG. 6). The second conductive pattern CP2 may be formed in the same process step as the second connection electrode CN2 (see FIG. 6). The second conductive pattern CP2 may have a single-layer or multi-layer structure and have the same stacked structure as the second connection electrode CN2 (see FIG. 6). For example, the second conductive pattern CP2 may have a three-layer structure of titanium/aluminum/titanium. The second conductive pattern CP2 may have the same thickness as the first connection electrode CN2 (see FIG. 6).

The signal pad PD may further include a pad insulating layer disposed between the first conductive pattern CP1 and the second conductive pattern CP2 and having an insulating layer opening which exposes the first conductive pattern CP1. For example, the pad insulating layer disposed between the first conductive pattern CP1 and the second conductive pattern CP2 may be a layer in which the fifth insulating layer 50 (see FIG. 6) of the aforementioned display region DA (see FIG. 6) extends to the pad region PA1 or PA2.

The second pad insulating layer IL2-PD may include the same material as the base layer IL1 of the aforementioned input sensing unit ISP (see FIG. 6). The second pad insulating layer IL2-PD may be formed in the same process step as the base layer IL1. The second pad insulating layer IL2-PD may include an inorganic film. For example, the inorganic film may include at least one of aluminum oxide, titanium oxide, silicon oxide, silicon nitride, silicon oxynitride, zirconium oxide, or hafnium oxide.

A second insulating layer opening OP-IL2 may be defined in the second pad insulating layer IL2-PD. The second insulating layer opening OP-IL2 may expose the second conductive pattern CP2. The third conductive pattern CP3 may be connected to the second conductive pattern CP2 through the second insulating layer opening OP-IL2.

The third conductive pattern CP3 may be disposed on the second conductive pattern CP2. In a plan view, the third conductive pattern CP3 may overlap the second conductive pattern CP2. In FIG. 8A, for convenience, the second conductive pattern CP2 and the third conductive pattern CP3 are illustrated in a plan view as completely overlapping each other, but the second conductive pattern CP2 may be disposed inside the third conductive pattern CP3, or the third conductive pattern CP3 may be disposed inside the second conductive pattern CP2.

The third conductive pattern CP3 may include the same material as the first sensing conductive layer CL1 or the second sensing conductive layer CL2 of the aforementioned display region DA (see FIG. 6). For example, the third conductive pattern CP3 may include the same material as the second sensing conductive layer CL2 of the aforementioned display region DA (see FIG. 6). The third conductive pattern CP3 may be formed in the same process step as the second sensing conductive layer CL2. The third conductive pattern CP3 may have a multi-layer structure and have the same stacked structure as the second sensing conductive layer CL2. The third conductive pattern CP3 may have the same thickness as the second sensing conductive layer CL2.

The third conductive pattern CP3 may include a first layer disposed on the second conductive pattern CP2, a second layer disposed on the first layer, and a third layer disposed on the second layer. The thickness of the second layer may be greater than the thickness of each of the first and third layers. The second layer may have higher conductivity than the first and third layers. The first and third layers may include the same material as each other. The second layer may include a different material from the first and third layers. For example, the first layer and the third layer may include titanium (Ti), and the second layer may include aluminum (Al). When pressure is applied during a bonding process, the third layer disposed at the uppermost portion of the third conductive pattern CP3 is stretched and torn by the pressure, thereby exposing the second layer so which the second layer may be connected to a bump electrode of an electronic component.

The insulating pattern PP may be disposed between the second conductive pattern CP2 and the third conductive pattern CP3. The lower surface of the insulating pattern PP may be in contact with the second conductive pattern CP2, and each of the side surface and the upper surface of the insulating pattern PP may be covered by the third conductive pattern CP3. The insulating pattern PP may form a protruding portion in the pad region PA1 or PA2.

In a plan view, the insulating pattern PP may overlap each of the second conductive pattern CP2 and the third conductive pattern CP3. In this embodiment, the insulating pattern PP may be arranged along the second direction DR2. The insulating patterns PP may be spaced apart from each other in the second direction DR2. In a plan view, the insulating pattern PP may be disposed inside the first insulating layer opening OP-IL1. In a plan view, the insulating pattern PP may be disposed inside the second insulating layer opening OP-IL2.

In FIG. 8A and FIG. 8B, a structure in which three insulating patterns PP are arranged in a row is exemplarily illustrated, but the number and arrangement of the insulating patterns PP are not limited thereto. In addition, FIG. 8A depicts a structure in which the planar shape of the insulating pattern PP is rectangular is exemplarily illustrated, but the embodiment of the inventive concept is not limited thereto. The planar shape of the insulating pattern PP may be changed to a polygon, circle, oval, etc., other than the rectangle. In addition, the shapes of the insulating patterns PP are not limited to being the same as each other.

The insulating pattern PP may be formed from a polymer material. For example, the insulating pattern PP may include a thermosetting polymer. Without being limited thereto, however, the insulating pattern PP may also include a thermoplastic polymer.

The insulating pattern PP may be provided in plurality. One insulating pattern PP may include a first insulating pattern PP1 and a second insulating pattern PP2. The first insulating pattern PP1 and the second insulating pattern PP2 may be disposed at the same layer as each other. The first insulating pattern PP1 and the second insulating pattern PP2 may be disposed between the second conductive pattern CP2 and the third conductive pattern CP3. The first insulating pattern PP1 and the second insulating pattern PP2 may be disposed in contact with each other.

The first insulating pattern PP1 may include a lower surface adjacent to the second conductive pattern CP2, an upper surface opposite the lower surface, and a side surface connecting the lower surface and the upper surface to each other. The second insulating pattern PP2 may include a lower surface adjacent to the second conductive pattern CP2, an upper surface opposite the lower surface, and a side surface connecting the lower surface and the upper surface to each other. A portion of the side surface of the first insulating pattern PP1 and a portion of the side surface of the second insulating pattern PP2 may be in contact with each other.

The upper surface of the first insulating pattern PP1 may include a flat surface. The upper surface of the first insulating pattern PP1 may include a straight line on a cross section. The first insulating pattern PP1 may be formed from a negative photoresist material. The negative photoresist material may refer to a substance in which an unexposed portion is dissolved in a developing solution. Since the first insulating pattern PP1 is formed from the negative photoresist material, the upper surface may be formed to include a flat surface without an additional process step.

The upper surface of the second insulating pattern PP2 may include a curved surface. The upper surface of the second insulating pattern PP2 may include a curved surface on a cross section. The second insulating pattern PP2 may be formed from a positive photoresist material. The positive photoresist material may refer to a substance in which an exposed portion is dissolved in a developing solution. Since the second insulating pattern PP2 is formed from the positive photoresist material, the upper surface may be formed to include a curved surface without an additional process step.

The hardness of the first insulating pattern PP1 may be greater than the hardness of the second insulating pattern PP2. For example, the hardness of the first insulating pattern PP1 may be about twice the hardness of the second insulating pattern PP2. The hardness of the first insulating pattern PP1 may be about 5 GPa to about 15 GPa, and the hardness of the second insulating pattern PP2 may be about 1 GPa to about 5 GPa.

As the hardness of the first insulating pattern PP1 is greater than which of the second insulating pattern PP2, as illustrated in FIG. 8C, in a bonding pressure process, the first insulating pattern PP1 may have less deformation than the second insulating pattern PP2, easily penetrate the bump electrode, and receive concentrated pressure. Accordingly, as pressure is concentrated on the third conductive pattern CP3 on the first insulating pattern PP1, the outermost layer (e.g., the third layer) of the third conductive pattern CP3 is stretched and torn, and the intermediate layer (e.g., the second layer) is exposed, so which resistance to the bump electrode can be secured. In addition, the second insulating pattern PP2 may provide support due to its elasticity in the bonding pressure process, thereby being able to secure bonding reliability.

FIG. 8C exemplarily illustrates a bump electrode BMP of the data driver DDV (see FIG. 7) as an electronic component.

Through a bonding process, the bump electrode BMP may pass through the first adhesive layer CF1 to come in contact with the third conductive pattern CL3. As the display device DD according to the disclosure does not include a conductive ball, it is possible to prevent short-circuit defects caused by the conductive ball and/or electrical conduction defects when the conductive ball is not disposed, thus making it advantageous to implement a high-resolution panel.

As the insulating pattern PP according to the disclosure includes the first insulating pattern PP1 having high hardness and the second insulating pattern PP2 having low hardness, resistance to the bump electrode BMP may be secured by the first insulating pattern PP1, and bonding reliability may be secured by the second insulating pattern PP2.

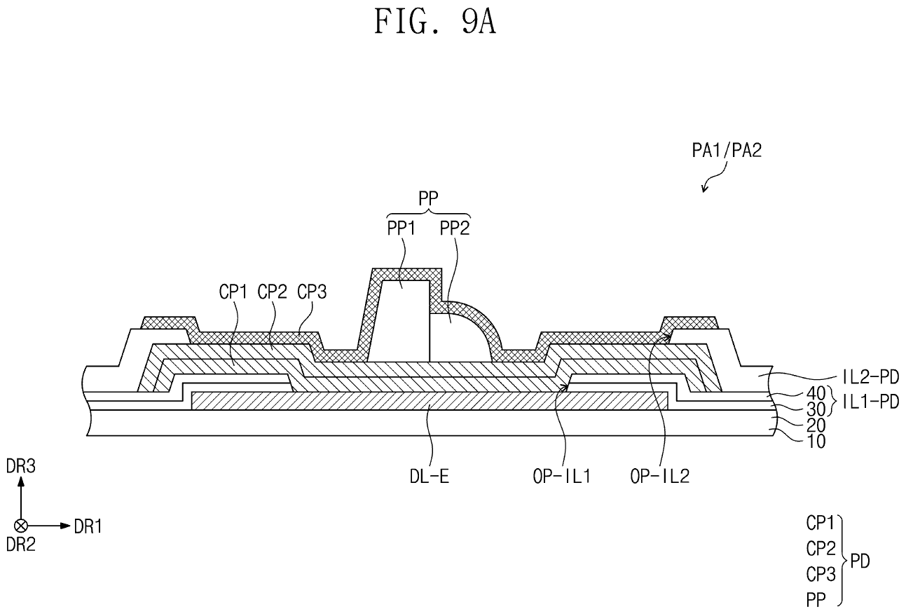

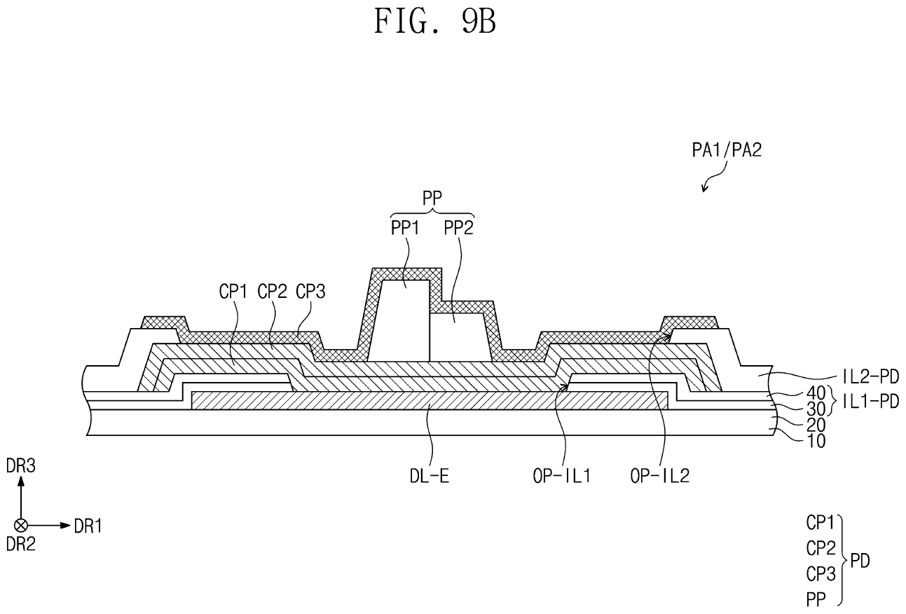

Each of FIG. 9A and FIG. 9B is a cross-sectional view of the pad region according to an embodiment of the inventive concept. Each of FIGS. 9A and 9B is a cross-sectional view of another embodiment corresponding to line A-A′ of FIG. 8A.

Referring to FIGS. 9A and 9B, the thickness of the first insulating pattern PP1 may be greater than the thickness of the second insulating pattern PP2. The height of the first insulating pattern PP1 may be greater than the height of the second insulating pattern PP2. Here, the thickness and height of the first insulating pattern PP1 and the second insulating pattern PP2 may refer to the length in the third direction DR3. Accordingly, the first insulating pattern PP1 may protrude in a direction toward the third conductive pattern CP3 compared to the second insulating pattern PP2.

Referring to FIG. 9A, the upper surface of the first insulating pattern PP1 may include a flat surface, and the upper surface of the second insulating pattern PP2 may include a curved surface. Here, the first insulating pattern PP1 may be formed from a negative photoresist material, and the second insulating pattern PP2 may be formed from a positive photoresist material.

Referring to FIG. 9B, each of the upper surface of the first insulating pattern PP1 and the upper surface of the second insulating pattern PP2 may include a flat surface. Here, each of the first insulating pattern PP1 and the second insulating pattern PP2 may be formed from a negative photoresist material.

As illustrated in FIGS. 9A and 9B, since the first insulating pattern PP1 has a structure which protrudes compared to the second insulating pattern PP2, in the bonding pressure process, the first insulating pattern PP1 may easily penetrate the bump electrode and receive concentrated pressure. Accordingly, as pressure is concentrated on the third conductive pattern CP3 on the first insulating pattern PP1, the outermost layer (e.g., the third layer) of the third conductive pattern CP3 is stretched and torn, and the intermediate layer (e.g., the second layer) is exposed, so which resistance to the bump electrode can be secured. In addition, the second insulating pattern PP2 may provide support due to its elasticity in the bonding pressure process, thereby being able to secure bonding reliability.

According to the above description, the display panel and the electronic apparatus including the same according to an embodiment of the inventive concept may have excellent bonding reliability.

Although the above has been described with reference to preferred embodiments of the inventive concept, those skilled in the art or those of ordinary skill in the art will understand which various modifications and changes can be made to the inventive concept within the scope which does not depart from the spirit and technical field of the inventive concept described in the claims to be described later. Accordingly, the technical scope of the inventive concept should not be limited to the content described in the detailed description of the specification, but should be determined by the claims described hereinafter.

What is claimed is:

1. A display panel in which a display region including a pixel and a non-display region disposed adjacent to the display region and including a pad region are defined,
wherein a signal pad connected to the pixel through a signal line is disposed in the pad region,
wherein the signal pad comprises:
a first conductive pattern connected to a portion of the signal line;
a second conductive pattern disposed on the first conductive pattern;
a third conductive pattern disposed on the second conductive pattern; and
an insulating pattern disposed between the second conductive pattern and the third conductive pattern,
wherein the insulating pattern comprises:
a first insulating pattern; and
a second insulating pattern disposed at a same layer as the first insulating pattern,
wherein the first insulating pattern and the second insulating pattern are in contact with each other; and
wherein a hardness of the first insulating pattern is greater than a hardness of the second insulating pattern.

2. The display panel of claim 1, wherein each of the first insulating pattern and the second insulating pattern comprises a lower surface adjacent to the second conductive pattern, an upper surface opposite the lower surface, and a side surface connecting the lower surface and the upper surface to each other, and
a portion of the side surface of the first insulating pattern and a portion of the side surface of the second insulating pattern are in contact with each other.

3. The display panel of claim 2, wherein:
the upper surface of the first insulating pattern comprises a flat surface; and
the upper surface of the second insulating pattern comprises a curved surface.

4. The display panel of claim 3, wherein:
the first insulating pattern is formed from a negative photoresist material; and
the second insulating pattern is formed from a positive photoresist material.

5. The display panel of claim 2, wherein:
the upper surface of the first insulating pattern comprises a flat surface; and
the upper surface of the second insulating pattern comprises a flat surface.

6. The display panel of claim 5, wherein:
the first insulating pattern is formed from a negative photoresist material; and
the second insulating pattern is formed from a negative photoresist material.

7. The display panel of claim 1, wherein:
the hardness of the first insulating pattern is about 5 GPa to about 15 GPa; and
the hardness of the second insulating pattern is about 1 GPa to about 5 GPa.

8. The display panel of claim 1, wherein a thickness of the first insulating pattern is same as a thickness of the second insulating pattern.

9. The display panel of claim 1, wherein:
a thickness of the first insulating pattern is greater than a thickness of the second insulating pattern; and
the first insulating pattern protrudes in a direction toward the third conductive pattern compared to the second insulating pattern.

10. The display panel of claim 1, wherein:
the insulating pattern is provided in plurality; and
the plurality of insulating patterns are spaced apart from each other in a plane view.

11. A display panel in which a display region including a pixel and a non-display region adjacent to the display region and including a pad region are defined,
wherein a signal pad connected to the pixel through a signal line is disposed in the pad region,
wherein the signal pad comprises:
a first conductive pattern connected to a portion of the signal line;
a second conductive pattern disposed on the first conductive pattern;
a third conductive pattern disposed on the second conductive pattern; and
an insulating pattern disposed between the second conductive pattern and the third conductive pattern,
wherein the insulating pattern comprises:
a first insulating pattern; and
a second insulating pattern disposed at a same layer as the first insulating pattern,
wherein the first insulating pattern and the second insulating pattern are in contact with each other,
wherein a thickness of the first insulating pattern is greater than a thickness of the second insulating pattern, and
wherein the first insulating pattern protrudes in a direction toward the third conductive pattern compared to the second insulating pattern.

12. The display panel of claim 11, wherein each of the first insulating pattern and the second insulating pattern comprises:
a lower surface adjacent to the second conductive pattern;
an upper surface opposite the lower surface; and
a side surface connecting the lower surface and the upper surface to each other, and
a portion of the side surface of the first insulating pattern and a portion of the side surface of the second insulating pattern are in contact with each other.

13. The display panel of claim 12, wherein:
the upper surface of the first insulating pattern comprises a flat surface; and
the upper surface of the second insulating pattern comprises a curved surface.

14. The display panel of claim 13, wherein:
the first insulating pattern is formed from a negative photoresist material; and
the second insulating pattern is formed from a positive photoresist material.

15. The display panel of claim 12, wherein:
the upper surface of the first insulating pattern comprises a flat surface; and
the upper surface of the second insulating pattern comprises a flat surface.

16. The display panel of claim 15, wherein:
the first insulating pattern is formed from a negative photoresist material; and
the second insulating pattern is formed from a negative photoresist material.

17. The display panel of claim 11, wherein a hardness of the first insulating pattern is greater than a hardness of the second insulating pattern.

18. The display panel of claim 17, wherein:
the hardness of the first insulating pattern is about 5 GPa to about 15 GPa; and
the hardness of the second insulating pattern is about 1 GPa and about 5 GPa.

19. The display panel of claim 12, wherein:
the insulating pattern is provided in plurality; and
the plurality of insulating patterns are spaced apart from each other in a plane view.

20. An electronic apparatus comprising:
a display module comprising a display panel, which includes a display region including a pixel and a non-display region including a pad region and adjacent to the display region, and an input sensing unit disposed on the display panel;
an electronic component comprising a bump electrode and disposed on the pad region; and
an adhesive layer which bonds the display panel and the electronic component to each other,
wherein a signal pad connected to the pixel through a signal line is disposed in the pad region,
wherein the signal pad comprises:
a first conductive pattern connected to a portion of the signal line;
a second conductive pattern disposed on the first conductive pattern;
a third conductive pattern disposed on the second conductive pattern; and
an insulating pattern disposed between the second conductive pattern and the third conductive pattern,
wherein the insulating pattern comprises:
a first insulating pattern, and
a second insulating pattern disposed at a same layer as the first insulating pattern,
wherein the first insulating pattern and the second insulating pattern are in contact with each other,
wherein a thickness of the first insulating pattern is greater than a thickness of the second insulating pattern,
wherein the first insulating pattern protrudes in a direction toward the third conductive pattern compared to the second insulating pattern, and
wherein a hardness of the first insulating pattern is greater than a hardness of the second insulating pattern.
